(19) United States
(12) Patent Application Publication
(10) Pub. No.: US 2008/0247101 A1
(43) Pub. Date: Oct. 9, 2008

(54) ELECTRONIC DEVICE AND METHOD

(75) Inventors: Akram A. Salman, Santa Clara, CA (US); Stephen G. Beebe, Los Altos, CA (US); Mario M. Pelella, Mountain View, CA (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: ADVANCED MICRO DEVICES, INC., Sunnyvale, CA (US)

(21) Appl. No.: 11/697,859

(22) Filed: Apr. 9, 2007

(51) Int. Cl. H02H 9/00; H01L 27/12

(52) U.S. Cl. 361/56; 257/350; 257/E27.112

(57) ABSTRACT

An IO buffer is formed having a substrate resistor at a support layer of a semiconductor on insulator substrate. A diode junction is formed between the substrate resistor and portion of the semiconductor on insulator substrate underlying the substrate resistor. In the event of a high-voltage event, current will flow through the diode junction.

### FIELD OF THE DISCLOSURE

The present disclosure relates generally to devices having a semiconductor device, and more particularly to devices having a semiconductor device with an IO buffer having a substrate resistor.

### BACKGROUND

High-voltage events such as electrostatic discharge events are capable of destroying electronic circuitry at integrated circuit devices. To protect against such high-voltage events, various protection devices are manufactured at integrated circuit devices. For example, diodes are commonly formed at a device layer, along with transistors, of an integrated circuit and connected to IO pads capable of shunting current associated with electro-static discharge events at the IO pads. Formation of these transistors requires additional space to form the IO buffers. Therefore, a method overcoming this problem would be useful.

### BRIEF DESCRIPTION OF THE DRAWINGS

The present disclosure may be better understood, and its numerous features and advantages made apparent to those skilled in the art by referencing the accompanying drawings, in which like reference numbers indicate similar or identical items.

FIG. 1 illustrates a specific embodiment of a block diagram including a semiconductor device in accordance with the present disclosure;

FIG. 2 illustrates a cross-sectional view of a portion of a semiconductor device at the semiconductor device FIG. 1 in accordance with a specific embodiment of the present disclosure;

FIG. 3 illustrates a specific embodiment of an output-only IO buffer in accordance with a specific embodiment of the present disclosure;

FIG. 4 illustrates a specific embodiment of an input-only IO buffer in accordance with a specific embodiment of the present disclosure;

FIG. 5 illustrates a specific embodiment of an bidirectional IO buffer in accordance with a specific embodiment of the present disclosure;

FIG. 6 illustrates a schematic and block diagram of a bidirectional IO buffer in accordance with a specific embodiment of the present disclosure;

FIG. 7 illustrates an overhead view of a region at which a substrate resistor is formed in accordance with a specific embodiment of the present disclosure;

FIGS. 8-16 illustrate a workpiece at various stages of processing a substrate resistor; and

FIG. 17 illustrates a method in accordance with a specific embodiment of the present disclosure.

### DETAILED DESCRIPTION

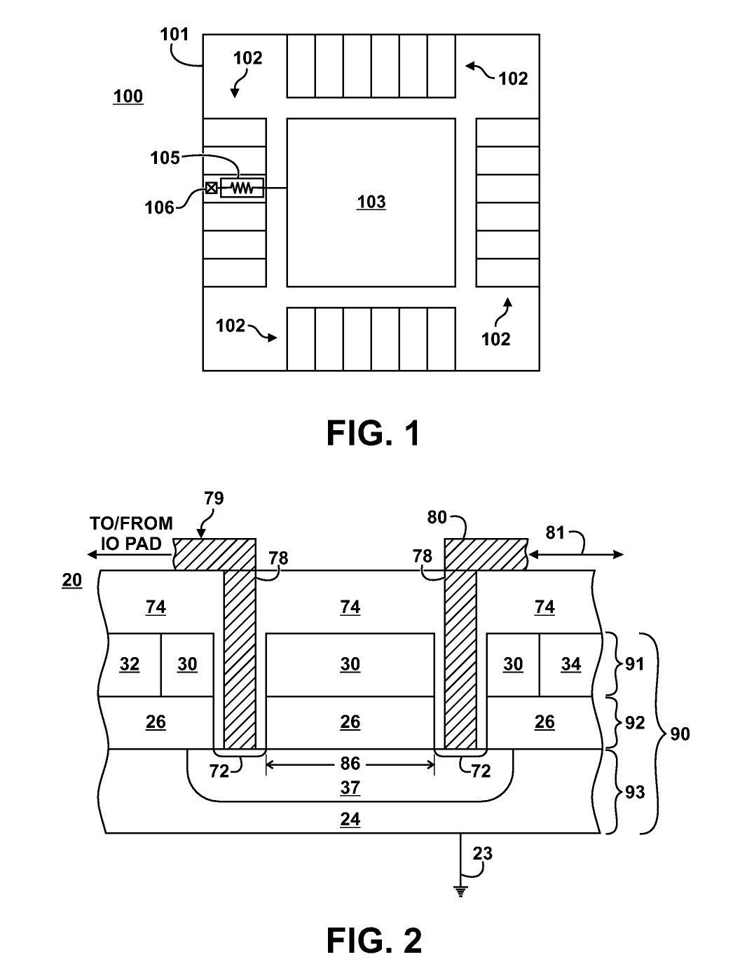

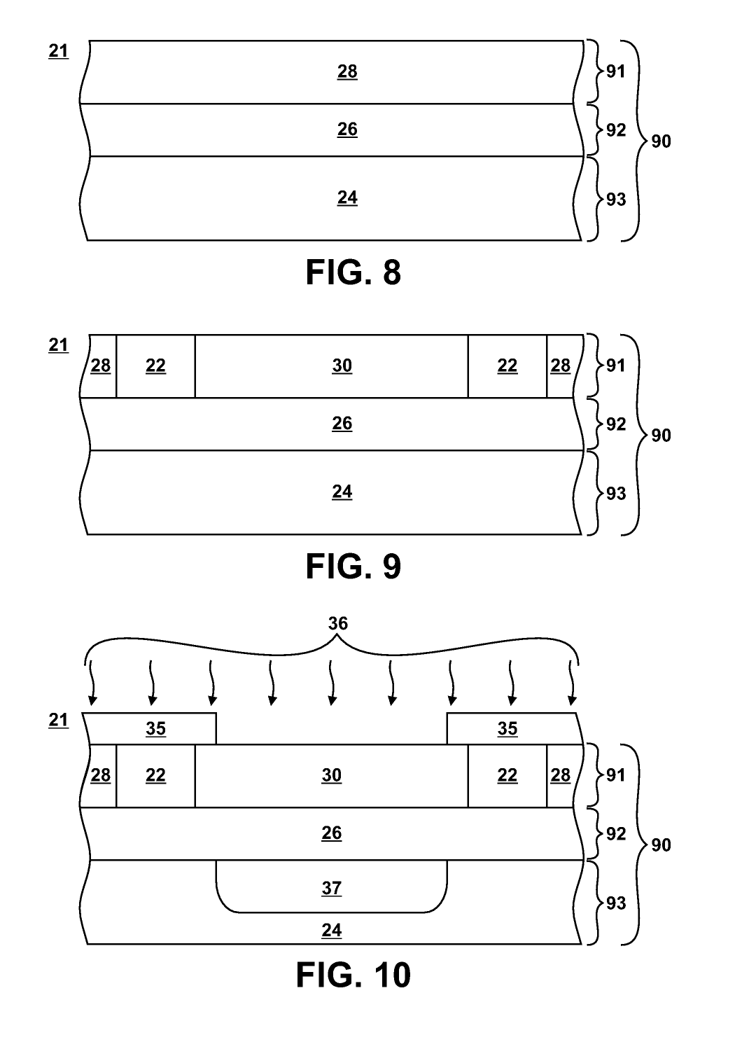

A device implementing a SOI substrate resistor within an IO buffer is disclosed. Specific embodiments of the present disclosure will be better understood with reference to FIGS. 1-7, of which, FIGS. 1-5 represent various embodiment of IO buffers, and FIGS. 8-16 represent a specific method of forming a substrate resistor.

FIG. 1 illustrates a device 100 that specifically includes a semiconductor device 101. The integrated circuit device 101 can be connected to other integrated circuit devices to form part of the larger device 100. The semiconductor device 101 includes IO regions 102 having a plurality of IO buffers. The plurality IO buffers provide electrical and physical interfaces for input and output signals passed between core region 103 and other specific devices external to integrated circuit device 101. A specific IO buffer 106 of the plurality of IO buffers within IO regions 102 is identified at FIG. 1. IO buffer 106 includes an IO pad 109 connected to a resistor 105 that is a substrate resistor formed at the support layer of a semiconductor-on-insulator (SOI) substrate. A specific embodiment resistor 105 is illustrated in FIG. 2.

As used herein the term “IO pad” is intended to mean a conductive structure of the semiconductor device at which an input signal is received from external the semiconductor device that is to be provided to a core region of the semiconductor device, or at which an output signal is received from circuitry of the IO buffer that is to be provided external the semiconductor device. Examples of IO buffers include input-only IO buffers, output-only IO buffers, and bidirectional IO buffers. As used herein, the term IO buffer is intended to mean an IO pad and that portion of a semiconductor device that is primarily responsible for the physical and electrical signal interface between the IO pad and a core region of the semiconductor device.

FIG. 2 illustrates a cross-sectional view of a portion of a semiconductor device at which an SOI substrate resistor, such as resistor 105 has been formed. FIG. 2 illustrates a SOI substrate 90, having levels 91, 92, and 93 that correspond to levels having a device layer, dielectric layer, and semiconductor support layer, respectively. Region 37 represents an N-doped region formed within the P-doped semiconductor support layer 24. Regions 72 represent silicide contact regions electrically connected to contact plugs 78. A conductive interconnect 79, such as a metal trace is connected to an IO pad (not shown). A conductive interconnect 80 is connected to another device of the integrated circuit device 20. A resistance of the substrate resistor of FIG. 2 is based upon the length 86 between the silicide contact regions 72. A resistance of the substrate resistor is between 10-50 ohms when the resistor is an output resistor, while a resistance of the substrate resistor is between 50-300 ohms when the resistor is an input resistor. The substrate resistor 105 will be discussed in greater detail with reference to FIGS. 8-16.

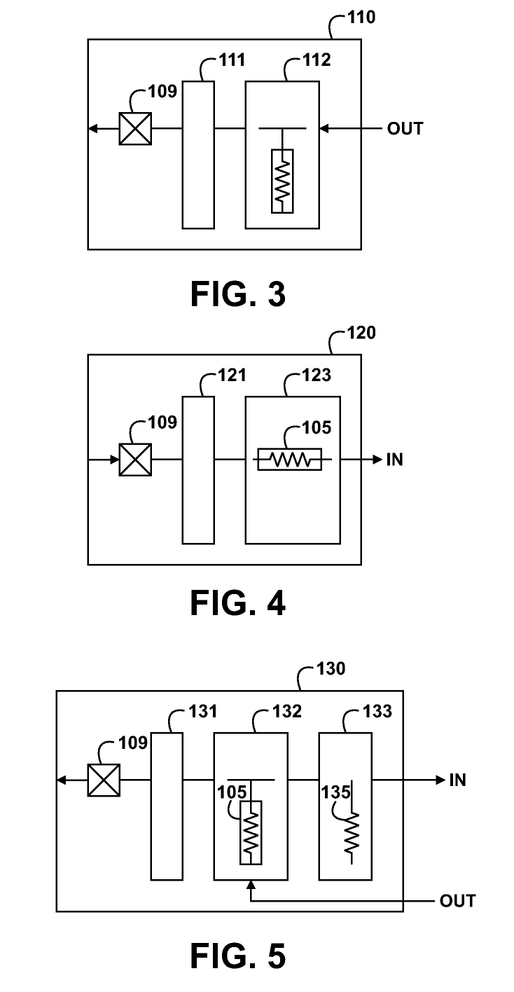

FIG. 3 illustrates a specific embodiment of an IO buffer 110 that can correspond to IO buffer 106 of FIG. 1. IO buffer 110 is an output-only IO buffer, and includes a primary ESD (Electro-Static Discharge) portion 111 and an output driver portion 112. The output driver portion 112 includes the substrate resistor 105 and other circuitry that is used to provide an interface for an output signal received from the core of a semiconductor device (OUT), and provides the conditioned signal to the IO pad 109. A more detailed implementation of an output driver is discussed with reference to FIG. 6. The primary ESD portion 110 is that portion of the IO buffer 110 dedicated to addressing potential ESD events. For example, it is well known to connect a diode commonly referred to as an IO diode between the IO pad and Vdd, and another IO diode between the IO pad and GND using diodes formed at the device layer of a SOI substrate. However, as will be further discussed with reference to FIG. 6, a specific embodiment of the present disclosure may allow one of these IO diodes to be eliminated.

FIG. 4 illustrates a specific embodiment of an input-only IO buffer 120 that can correspond to IO buffer 106 of FIG. 1. IO buffer 120 is an input-only IO buffer, and includes a primary ESD (Electro-Static Discharge) portion 121 and an input receiver portion 123. The input receiver portion 123 includes the substrate resistor 105 and other circuitry that is used to provide an interface for an input signal received at IO pad 109 from external the semiconductor device, and provides the conditioned signal (IN) to the core of a semiconductor device. A more detailed implementation of an input receiver is discussed with reference to FIG. 6. The primary ESD portion 123 corresponds to primary ESD portion 111 of FIG. 3.

FIG. 5 illustrates a specific embodiment of a bidirectional IO buffer 130 that can correspond to IO buffer 106 of FIG. 1. IO buffer 130 is a bidirectional IO buffer, and includes a primary ESD portion 131, output driver portion 132 and an input receiver portion 133. The output driver portion 132 includes the substrate resistor 105 and corresponds to output driver portion 122 previously discussed. The input receiver portion 133 includes a resistor 135, which may or may not be a substrate resistor similar to substrate resistor 105, and other circuitry that is used to provide an interface for an input signal received at IO pad 109 from external the semiconductor device, and provides the conditioned signal (IN) to the core of a semiconductor device. The primary ESD portion 131 corresponds to primary ESD portion 111 of FIG. 3. Operation of the bidirectional IO buffer 130 will be discussed with reference to FIG. 6, which illustrates a specific implementation of a bidirectional IO buffer.

FIG. 6 illustrates a bidirectional IO buffer 200 that can correspond to the IO buffer 130 of FIG. 5, and to portion of the IO buffers of FIGS. 3 and 4. With respect to FIG. 5, the bidirectional IO buffer 200 illustrates primary ESD portion 131, output driver portion 132, and an input receiver portion 133.

IO buffer 200 includes an IO pad 109 connected to the anode of diode 214 that is part of the primary ESD portion 131. The cathode of diode 214 is connected to a voltage reference node labeled Vdd, which during operation provides a drain voltage.

The output driver portion 132 illustrated in FIG. 6 includes a PMOS transistor 227 having a first source/drain electrode connected to the voltage reference node Vdd, a second source/drain electrode, and a control electrode electrode. Note that the term source/drain electrode is used generically to indicate a source electrode, a drain electrode, or an electrode that can operate as either a source electrode or a drain electrode. A resistor 226 has a first electrode connected to the second source/drain electrode of transistor 227, and a second electrode. The substrate resistor 105 includes a first electrode connected to the second electrode of resistor 226, and a second electrode. An NMOS transistor 228 includes a first source/drain electrode connected to the second electrode of the substrate resistor 105, a second source/drain electrode connected to a voltage reference node labeled Vss, which provides a source reference voltage (typically ground) during operation, and a control gate.

The output driver portion 132 further includes an inverter buffer 221 having a first input to receive a control signal and an output connected to the control gate of transistor 227, and a non-inverting buffer 222 having an input connected to receive a control signal and output connected to the control gate of transistor 228. Note that a buffer can be used in place of inverter 221, or an inverter can be used in place of buffer 222, depending upon the control logic that drives these devices.

The input receiver portion 133 illustrated at FIG. 6 includes an input resistor (R_{IN}) 236 having a first electrode connected to the IO pad 109, and a second electrode. A diode 234, referred to as a Charged Device Model (CDM) diode, has an anode connected to the second electrode of resistor 236, and a cathode connected to the voltage reference node Vdd. A diode 239, also referred to as a CDM diode, has a cathode connected to the second electrode of resistor 236, and an anode connected to the voltage reference node Vss. In inverter is formed by the interconnection of transistors 237 and 238, wherein the control electrodes of transistors 237 and 238 are connected to the second electrode of resistor 236 to provide a output signal (IN) that is inverted from the signal received at their control electrodes.

As illustrated in FIG. 6, the output driver portion 132 is illustrated to include the substrate resistor 105 (resistor (226) can also be a substrate resistor which can help in the ESD protection). The use of a substrate resistor can eliminate the need to dedicate space at a higher layer of the semiconductor device for forming a resistor, such as a polysilicon resistor. Furthermore, substrate resistor 105 in IO buffer 200 includes a p-n junction at an interface with the semiconductor support substrate to eliminate the need for a second IO protection diode between the IO pad 209 and VSS. Therefore, referring to FIG. 2, during a negative high-voltage event, such as an ESD event, at IO pad 109 will cause at least portions of the region 37 forming of resistor 109 to become forward biased relative the semiconductor support layer 24, which is connected to Vss. Therefore, current will flow through the p-n junction from the IO pad 209 to the substrate 24, thereby protecting circuitry of IO buffer 200. This is an advantage over the prior art in that a separate IO diode need not be formed at the device layer, thereby reducing the space needed to implement the buffer 200 as well as the capacitance at IO pad 109. In an alternate embodiment, the use of the substrate diode may not eliminate the need for a separate IO diode (i.e., a diode can be connected between Vss and pad 209 in the same manner as diode 214 is connected between pad 209 and Vdd) but instead will provide additional protection during a high voltage event, or allow for an IO diode having reduced size.

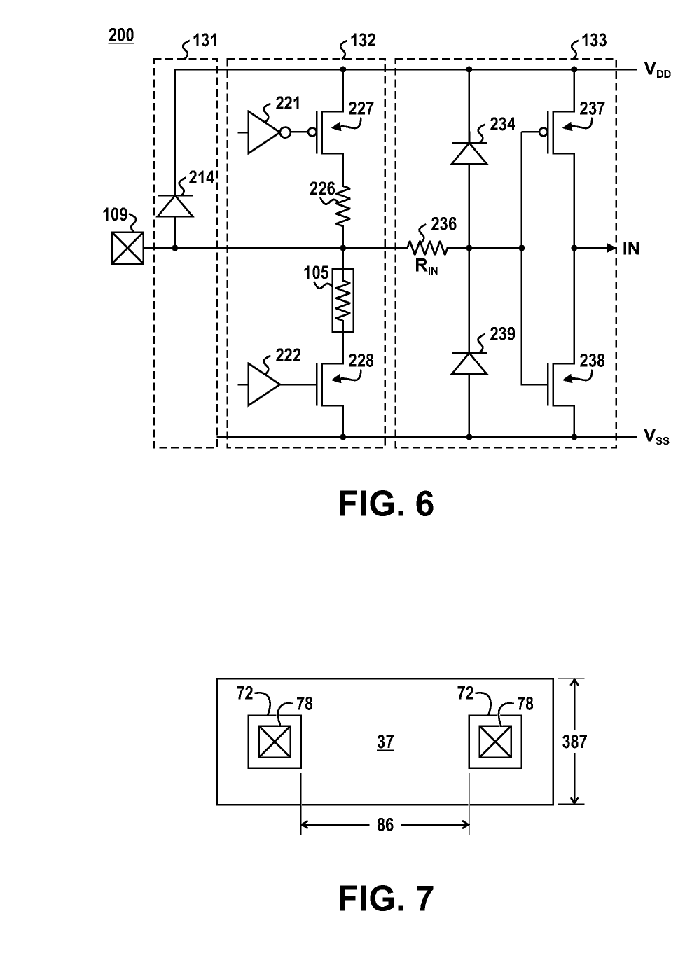

To eliminate the need for an IO diode between Vss and input pad 109, the doped region 37 of the substrate resistor 105, illustrated in FIG. 2, needs to have a size that will allow the parasitic diode, formed between itself and semiconductor support substrate 24, to withstand the current from the ESD event. It is expected that a minimum width of region 37 forming resistor 105 will be greater than 35 micro meters, assuming no other ESD protection on the IO pad to Vss, to assure a forward biased diode region below the contact electrically connected to the IO pad is formed having sufficient dimensions to ensure the ESD current can safely pass to ground. For example, referring to FIG. 7, region 37 has a length 86 between contact locations 78 that defines a resistive value of resistor 105 during normal operation, and a width 387 that ensures enough current can pass through region 37 during an ESD event. Note that while a single contact location has been illustrated at each end of the region 37 at FIG. 7, that multiple contacts can be used at each end to ensure the ESD current can be handled properly.

In an alternate embodiment, resistor 226 can also be formed as a substrate resistor to further facilitate shunting of ESD current. If both resistor 105 and 226 are ESD resistors, the width requirement of the substrate resistors will be greater than 25 micrometers, assuming no other ESD protection. It will be appreciated that the input resistor (Rin) of FIG. 6 can also be a substrate resistor of the same type as resistor 105, thereby providing additional protection during a high-voltage event, such as an ESD event.

FIGS. 8-15 illustrate a method for manufacturing an SOI substrate resistor such as resistor 105 previously discussed. FIG. 8 illustrates workpiece 21 representing a portion of a semiconductor integrated circuit device being manufactured using a MOS process and more specifically a CMOS process. Although the term “MOS device” properly refers to a device having a metal gate electrode and an oxide gate insulator, that term as used herein is meant to refer to any semiconductor device that includes a conductive gate electrode (whether metal or other conductive material) that is positioned over a gate insulator (whether oxide or other insulator) which, in turn, is positioned over a semiconductor substrate. Various steps in the manufacture of semiconductor integrated circuit devices are well known and so it will be appreciated that many conventional steps are only briefly mentioned herein or entirely omitted.

FIG. 8 illustrates an SOI substrate 90 that has three distinct levels, 91-93. A device layer 22 of SOI substrate 90 is resides at level 91, a dielectric layer 26 of SOI substrate 90 is resides at level 92, and a carrier layer 24 of SOI substrate 90 is resides at level 93. The device layer 22 is a semiconductor layer at which active devices, such as transistor are formed. The semiconductor material of device layer 22 is a relatively pure monocrystalline semiconductor material typically used in the semiconductor industry, such as silicon germanium, carbon, and the like, and combinations thereof, which can be mixed with other elements such as to form a substantially monocrystalline semiconductor material.

The dielectric layer 26 is commonly referred to as a buried oxide layer or “BOX” and is a dielectric material over which the device layer 22 is resides. It will be appreciated that dielectric materials that are not oxides can be used to form dielectric layer 26. The combined thickness provided by device layer 22 and dielectric layer 22 is insufficient to be handled absent additional support. Therefore, device layer 22 and dielectric layer 26 reside overlying a support layer 24 that is a relatively pure monocrystalline semiconductor material. The term semiconductor support layer is used herein to indicate that the support layer is a semiconductor material. In one embodiment, the support layer is a P-type semiconductor material having a typical doping of 5e15 to 1e16/cm³.

FIG. 9 illustrates workpiece 21 after formation of dielectric isolation regions 28 and 30 that extend through device layer 22 to dielectric layer 26. The dielectric isolation regions can be formed using well known shallow trench isolation (STI) techniques in which trenches are etched into device layer 22 are filled with a dielectric material such as deposited silicon dioxide, and the excess silicon dioxide is removed by CMP. STI regions 28 provide electrical isolation, as needed, between various devices of the CMOS circuit that are to be formed at device layer 26. In accordance with an embodiment of the present disclosure, STI region 30 aids in electrically isolating the device to be formed in carrier substrate 24 from the devices to be formed at device layer 22. Note that either before or after the formation of dielectric isolation regions 28, 30, portions of monocrystalline silicon layer 22 can be doped, for example by ion implantation, to form P-type regions 32 and N-type regions 34.

FIG. 10 illustrates workpiece 21 after formation of a photoresist layer 35 overlying device layer 22. Photoresist layer 35 is patterned to expose a portion of dielectric isolation region 30. The patterned photoresist is used as an ion implantation mask to allow implantation of conductivity determining ionic impurities, as indicated by arrows 36, into the surface of semiconductor support substrate 24 to form a doped region 37. For example, ions can be implanted into the support to obtain an N-type dopant concentration of approximately 1e15 to 1e16/cm³ to form N-type doped region 37 at which the substrate resistor will be formed.

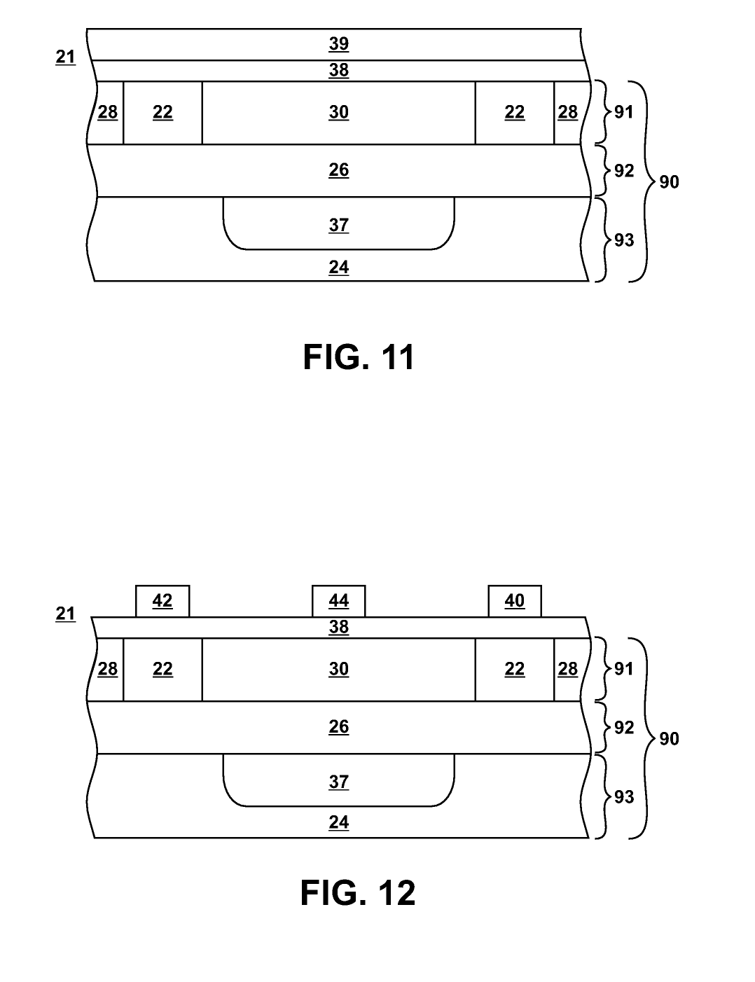

FIG. 11 illustrates workpiece 21 after removal of photoresist 35 and formation of a dielectric layer 38, which can be a layer at which gate dielectrics are formed, and a conductive layer 39, which can be a layer at which transistor gate electrodes are formed. Dielectric layer 38 can be grown or deposited on the surface of device layer 22. Layer 39 will hereinafter be referred to as a polycrystalline silicon layer although those of skill in the art will recognize that other conductive materials could be used as the gate electrode material.

FIG. 12 illustrates the workpiece 21 after polycrystalline gate electrode layer 39 has been patterned to form gate electrodes 40 and 42 overlying different portions of layer 22, at which N-channel and P-channel gate electrodes can be formed. The view perspective of FIG. 11 illustrates a length of spacer 44. The length of spacer 44 is selected to implement a desired resistance for the substrate resistor being formed. As previously discussed, in one embodiment, a width of regions 37, the dimension of region 37 perpendicular to the sheet at which FIG. 12 is illustrated, is at least 35 micrometers when a single substrate resistor is used, or at least 25 micrometers when two substrate resistors are used. The formation of patterned structures 40, 42, and 44 can be accomplished using well known patterning and etching techniques.

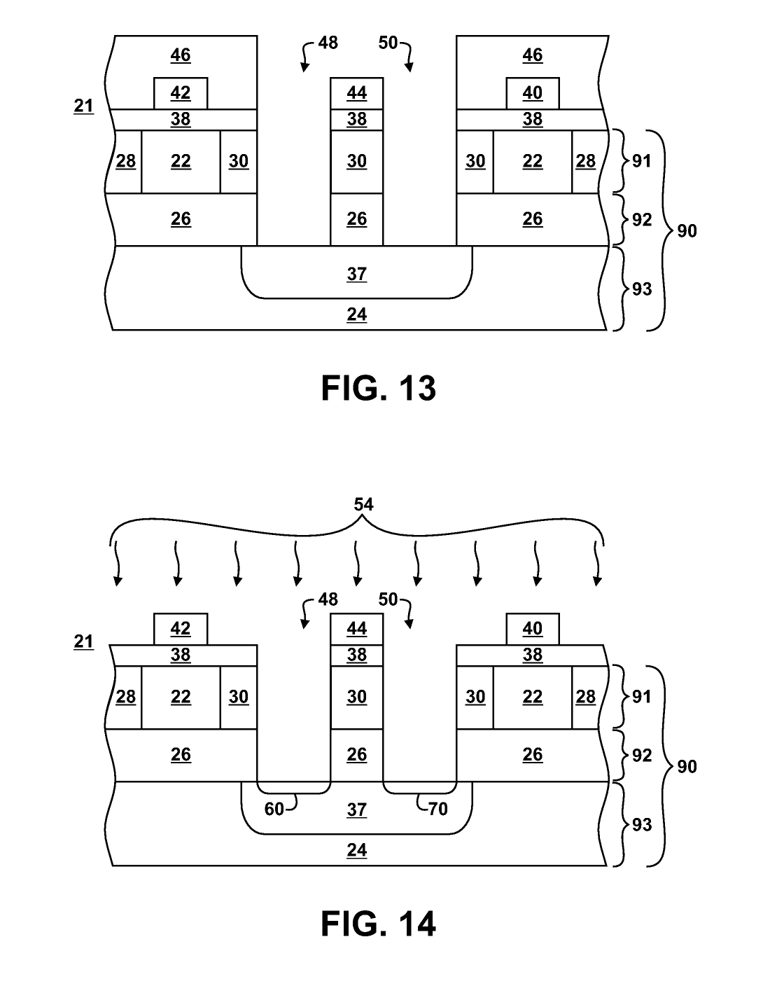

FIG. 13 illustrates workpiece 21 after a photoresist layer 46 is applied and patterning performed to expose a portion of dielectric isolation region 30 and spacer 44. In one embodiment, the patterned layer of photoresist 46 and spacer 44 are used together as an etch mask to etch openings 48 and 50 through dielectric isolation region 30 and dielectric insulating layer 26 and to expose portions of region 37. Openings 48 and 50 are anisotropically etched through dielectric isolation region 30 and dielectric insulating layer 26, preferably by reactive ion etching using well-known etching techniques.

FIG. 14 illustrates workpiece 21 after removal of photoresist layer 46 leaving openings 48 and 50 where contacts will be formed to provide electrical connections to the resistor being formed at region 37. Arrows 54 represent an N-type impurity dopant being applied to upper portions 60 and 70 at the region 30 to facilitate formation of a high-integrity electrical connection between region 30 and conductive plugs yet to be formed. For example, ions can be implanted into the region 30 to obtain an N-type dopant concentration of approximately 1e17/cm³ or higher, such as a dopant concentration from 1e17 to 5e18/cm³ to form N-type doped region 37 at which the substrate resistor will be formed. It will further be appreciated that a silicide (not shown) can also be formed at those portions of region 30 exposed at openings 48 and 50 to further facilitate formation of high integrity electrical connections.

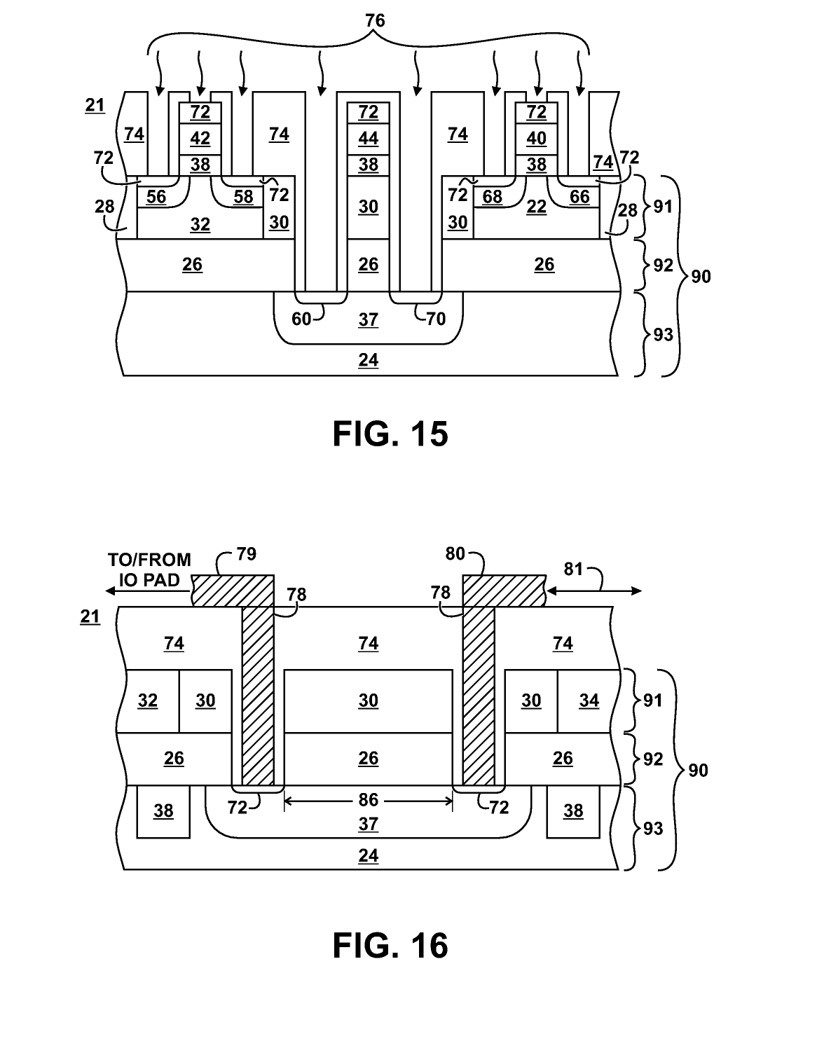

FIG. 15 illustrates workpiece 21 after formation of a layer 74 of insulating material that is typically deposited and planarized to cover the contact regions of workpiece 21. Note that FIG. 15 further illustrates that transistors can also be formed at the device layer. Following the planarization, a layer of photoresist (not illustrated) is applied to the surface of the planarized insulating material and is used as an etch mask to etch contact openings 76 that extend through the insulating material to the metal silicide contact regions.

FIG. 16 illustrates an alternate embodiment of a substrate resistor, wherein a guard ring 36 has been formed around the region 37. In the illustrated embodiment, the guard ring is a P-type region having a doping of 1e19 to 1e21/cm³, which is similar to a P-type source drain junction, and ensures that the substrate contact is close to the N+ contact of the resistor and to ensure a low resistance pat during a high-voltage event.

FIG. 2, previously discussed, illustrates contact plugs 78 in contact with contact location of the substrate resistor 37. The contact plugs can be formed, for example, by depositing successive layers of titanium, titanium nitride, and tungsten in known manner. One of the contact plugs is used to make electrical contact with the IO pad as indicated at FIG. 2 and previously discussed. In addition, the support substrate of the semiconductor device of FIG. 2 is electrically connected to ground to facilitate formation of forward biased diode junction during a negative high-voltage event, whereby current from the high-voltage event is shunted to ground.

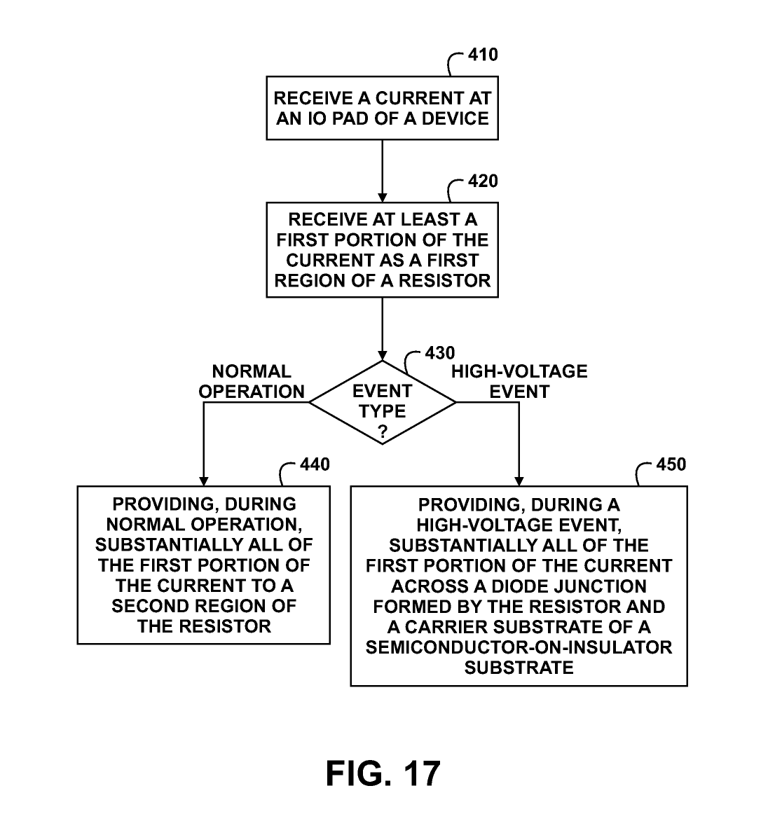

FIG. 17 illustrates a method in accordance with a specific embodiment of the present disclosure. At block 410, a current is received at an IO pad of a device. This current represents current that can be received during normal operation as a result of a signal being asserted or as a result of a high-voltage event.

At block 420, a portion of the received current is received a first region of a resistor. This portion of the current represents that portion received at the substrate resistor. The remaining portion of the current received at block 410 is provided to other devices connected to the IO pad.

At block 430 flow will either proceed to block 440 in the event of normal operation, or to block 450 in the event of a high-voltage event. At block 440, that portion of the current received at block 420 is provided through the resistor. For example, at least 99 percent of the current will flow through the resistor during normal operation.

At block 450, a high voltage event has occurred, and substantially all of the current received at block 420 is provided across a diode junction formed by the resistor and a SOI carrier substrate. For example, at least 90 percent or 95 percent of the current will flow through the resistor during normal operation.

Those of skill in the art will appreciate that alternative and/or additional steps may be used to fabricate the substrate resistor of workpiece 21 and the order of the method steps may be changed without departing from the broad scope of the invention. For example, sidewall spacers may be formed at the edges of the gate electrodes and those spacers may be used as masks for additional ion implantations or to space the metal silicide contacts apart from the gate electrodes. Similarly, substrate resistors can replace one or more of the resistors illustrated as connected to the IO pad in FIG. 6. For example, resistors 226 and 236 can be polysilicon resistors overlying the substrate resistor, i.e., at a level above level 93. Alternatively, one or both of resistors 226 and 236 can be substrate resistors formed at level 93. In addition, while the specific embodiment illustrated generally relates to providing a diode junction at resistor 105 that can be forward biased during a negative high-voltage event, it will be appreciated that in an alternate embodiment, a resistor can be formed whereby a diode junction will be forward biased in response to a positive-high voltage event.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. Accordingly, the present disclosure is not intended to be limited to the specific form set forth herein, but on the contrary, it is intended to cover such alternatives, modifications, and equivalents, as can be reasonably included within the spirit and scope of the disclosure.

What is claimed is:

1. A device comprising:
an IO pad overlying a semiconductor on insulator (SOI) substrate, the SOI substrate comprising a semiconductor support layer, a dielectric layer overlying the semiconductor support layer, and a semiconductor device layer overlying the dielectric layer; and
a resistor formed at the semiconductor support layer, the resistor comprising a first location electrically connected to the IO Pad.

2. The device of claim 1, wherein a diode junction is at an interface of the semiconductor support layer and the substrate resistor that allows current to flow d between the semiconductor support layer and the resistor during a high-voltage event at the IO pad, the semiconductor support layer having a first conductivity type and the substrate resistor having a second conductivity type.

3. The device of claim 2, wherein the first conductivity type is a P-type conductivity and the second conductivity type is an N-type conductivity.

4. The device of claim 2 wherein the resistor has a resistance of between 10 ohms to 50 ohms.

5. The device of claim 2 wherein the resistor has a resistance of between 50 ohms to 300 ohms.

6. The device of claim 2 wherein the resistor is a first resistor and further comprising:
a second resistor formed at a first level overlying the substrate resistor, the second resistor comprising a first location electrically connected to the IO pad.

7. The device of claim 2 wherein the resistor is a first resistor and the device further comprising:
a second resistor formed at the semiconductor support layer, the second resistor comprising a first location electrically connected to the IO pad.

8. The device of claim 2, wherein a width of the resister is at least 35 micro-meters.

9. The device of claim 2, wherein a width of the resister is at least 25 micro-meters.

10. The device of claim 2 further comprising:
a guard ring within the semiconductor support layer surrounding the resistor.

11. The device of claim 1 further comprising a transistor comprising a first source/drain electrode coupled to a second location of the substrate resistor, a second source/drain electrode and a control electrode, wherein a resistance of the substrate resistor is based upon a length of the resistor between the first location and the second location.

12. The device of claim 11, wherein the first location is defined by a first contact formed through a level at which the dielectric layer is formed, and the second location is defined by a second contact formed through the level.

13. The device of claim 11, wherein the second source/drain electrode is electrically connected to a voltage reference node.

14. The device of claim 1 further comprising:
a transistor comprising a first source/drain electrode, a second source/drain electrode, and a control electrode coupled to a second location of the resistor, wherein a resistance of the substrate resistor is based upon a length of the resistor between the first location and the second location.

15. The device of claim 14, wherein the transistor is a first transistor, and the device further comprising:
a second transistor comprising a first source/drain electrode, a second source/drain electrode coupled to the first source/drain electrode of the first transistor, and a control electrode coupled to the second location of the resistor.

16. A method comprising:
receiving at least a first portion of the current at a first region of a resistor;
providing, during normal operation, substantially all of the first portion of the current to a second region of the resistor; and
providing, during a high-voltage event, substantially all of the first portion of the current across a diode junction formed by the resistor and a carrier substrate of a semiconductor-on-insulator substrate.

17. The method of claim 16 wherein providing the current further comprises providing substantially all of the first portion of the current across the diode junction, wherein the diode junction is forward biased.

18. The method of claim 17 wherein substantially all of the current is greater than 90 percent of the first portion of the current.
